(19) United States
(12) Patent Application Publication
(10) Pub. No.: US 2019/0281729 A1
(43) Pub. Date: Sep. 12, 2019

(54) VAPOR CHAMBER

(71) Applicant: FURUKAWA ELECTRIC CO., LTD., Tokyo (JP)

(72) Inventors: Yoshikatsu INAGAKI, Tokyo (JP); Hirofumi AOKI, Tokyo (JP)

(73) Assignee: FURUKAWA ELECTRIC CO., LTD., Tokyo (JP)

(21) Appl. No.: 16/425,821

(22) Filed: May 29, 2019

Related U.S. Application Data
(63) Continuation of application No. PCT/JP2017/042793, filed on Nov. 29, 2017.

(30) Foreign Application Priority Data
Nov. 30, 2016 (JP) 2016-233123

(51) Int. Cl. H05K 7/20; G06F 1/20; F28F 9/26

(52) U.S. Cl. CPC H05K 7/20336; H04B 1/3827; F28F 9/26; G06F 1/203

(57) ABSTRACT

An object of the present disclosure is to provide a heat radiation member which excels in the cooling performance for a heat generator mounted in a thin casing and the thermal diffusion performance from the heat generator. A vapor chamber to be attached inside a casing includes: a flat plate-like container having a cavity portion; a wick structure provided to the cavity portion; a working fluid sealed in the cavity portion; and a resin attachment member, provided on the container, for attachment into the casing.

### CROSS REFERENCE TO RELATED APPLICATIONS

This is a continuation application of International Patent Application No. PCT/JP2017/042793 filed Nov. 29, 2017, which claims the benefit of Japanese Patent Application No. 2016-233123, filed Nov. 30, 2016, the full contents of all of which are hereby incorporated by reference in their entirety.

### BACKGROUND

### Technical Field

The present disclosure relates to a vapor chamber capable of being mounted in a thin casing.

### Background

In recent years, thinning of electric and electronic equipment has become more important. Meanwhile, with enhancement of the functions of electronic components such as semiconductor devices mounted in thin electric and electronic equipment, an increasing amount of heat is generated, and therefore cooling of these components has become more important. Moreover, with the increase in the amount of heat generated by the electronic components, it is also increasingly important to spread the heat generated from the electronic components to the periphery from the electronic components in order to prevent a worker from contacting the heat generated from the electronic components when handling the electric and electronic equipment.

A radiator plate may be used as a method of cooling a heat generator such as an electronic component mounted in a thin casing, or a method of spreading heat from the heat generator. Hence, for a thin tablet terminal, it was proposed to provide a radiator plate which is thermally connected with a linear heat pipe whose one end is thermally connected to a heat generator (Japanese Patent Application Publication No. 2016-161625). In Japanese Patent Application Publication No. 2016-161625, the radiator plate extends along the surface of a battery unit, and transfers heat from the heat generator to battery cells through the linear heat pipe. Further, in Japanese Patent Application Publication No. 2016-161625, flat plate-like fixing portions are formed on an outer peripheral portion of the radiator plate, and the radiator plate is fixed to a cover at the fixing portions with screws.

However, in Japanese Patent Application Publication No. 2016-161625, the radiator plate is a plate material and the heat pipe is linear in shape, and thus, with the thermal conductivity of the radiator plate and the heat transfer characteristics of the linear heat pipe, there was a case in which heat could not be sufficiently spread over the entire surface of the radiator plate. Therefore, in Japanese Patent Application Publication No. 2016-161625, it was also proposed to evenly transmit heat to the battery cells by attaching a thermal diffusion sheet to the radiator plate.

From the above, in Japanese Patent Application Publication No. 2016-161625, there is a problem that the cooling performance of the radiator plate and the heat spreading characteristics of the radiator plate are not sufficient in some case, and consequently there is a problem that the cooling performance for the heat generator and the thermal diffusion performance from the heat generator are not sufficient in some case.

In view of the above circumstances, it is an object of the present disclosure to provide a heat radiation member which excels in the cooling performance for a heat generator mounted in a thin casing and the thermal diffusion performance from the heat generator.

### SUMMARY

An aspect of the present disclosure is a vapor chamber to be attached inside a casing, the vapor chamber including: a flat plate-like container having a cavity portion; a wick structure provided to the cavity portion; a working fluid sealed in the cavity portion; and a resin attachment member, provided on the container, for attachment into the casing.

In the above aspect, the vapor chamber is attached and fixed inside a thin casing by the resin attachment member formed in the vapor chamber. The container of the vapor chamber is made of metal, and thus the container and the attachment member are formed of different kinds of members. Moreover, by thermally connecting a heat generator to the flat plate-like container at a position corresponding to the cavity portion, the heat generator is thermally connected to the vapor chamber.

The cavity portion of the vapor chamber extends along the plane direction of the container, the portion thermally connected to the heat generator functions as a heat receiving part, and a portion away from the heat receiving part functions as a heat radiating part. The cavity portion of the vapor chamber is in a depressurized state by a deaeration process. Therefore, the working fluid sealed in the cavity portion receives heat from the heat generator at the heat receiving part and undergoes a phase change from the liquid phase to the gas phase, and flows in the cavity portion from the heat receiving part to the heat radiating part. The gaseous working fluid that has flowed from the heat receiving part to the heat radiating part discharges the heat received from the heat generator at the heat radiating part and changes from the gas phase to the liquid phase, and the working fluid in the liquid phase is returned to the heat receiving part from the heat radiating part by the action of capillary forces stored in the cavity portion. Consequently, the heat from the heat generator thermally connected to the vapor chamber is smoothly spread over the entire plane of the vapor chamber.

An aspect of the present disclosure is the vapor chamber, wherein the resin attachment member is integrally molded with the container.

In the above aspect, the resin attachment member is not a separate member, but is integrated with the container.

An aspect of the present disclosure is the vapor chamber, wherein the resin attachment member is provided on a peripheral edge portion of the container.

An aspect of the present disclosure is the vapor chamber, wherein the resin attachment member is a fitting member which is detachably attached to a fitting part in the casing.

In the above aspect, since the vapor chamber is attached inside the casing with the use of fitting means, the vapor chamber does not need to be fixed using a screw.

An aspect of the present disclosure is a vapor chamber for use in cooling a heat generator mounted in a smartphone, a tablet terminal, or a notebook type personal computer.

According to the aspects of the present disclosure, since the vapor chamber, which is thermally connected to the heat generator by being attached inside the casing by the resin attachment member, can smoothly spread the heat received from the heat generator over the entire plane of the vapor chamber, it is possible to exhibit excellent cooling performance and thermal diffusion performance even for a heat generator mounted in a thin casing.

In order to manufacture a vapor chamber to be mounted in a thin casing, high precision for dimensions, particularly in the thickness direction, is required, and therefore a vapor chamber flattening step using a rolling mill or the like is necessary as a final step. According to the aspect of the present disclosure, even in the above technical circumstances, since the container and the attachment member are formed of different kinds of members, a highly accurate flatness can be obtained even for a vapor chamber having an attachment member by providing the attachment member on the container after the flattening step of the container. Moreover, by providing the attachment member on the container after the flattening step of the container, it is possible to improve the flattening step and consequently the production efficiency of the vapor chamber.

Additionally, according to the aspect of the present disclosure, by providing a resin attachment member on a container, even in a flat plate-like container, the strength of the attachment member can be improved by increasing the thickness of the resin constituting the attachment member, or the like. Furthermore, since the attachment member is made of resin, even when a stress is applied to the attachment member, it is possible to more reliably prevent deformation compared with a metal attachment member.

According to the aspect of the present disclosure, since the resin attachment member is integrally molded with the container, it is possible to facilitate the work of attaching the vapor chamber inside the casing. In addition, even when the size and shape of the attachment region of the vapor chamber vary in a plan view (the appearance viewed from a vertical direction with respect to the container plane), if the size and shape in plan view of the resin attachment member are changed, the vapor chamber can be attached inside the casing without changing the size and shape of the container, and therefore the degree of freedom in designing the vapor chamber and the heat generator is improved.

According to the aspect of the present disclosure, since the resin attachment member is a fitting member, the attachment member does not need to be fixed using a screw, thereby facilitating the attachment of the vapor chamber into the casing. Moreover, since the resin attachment member is the fitting member, there is no need to provide a screw hole portion for engaging a screw in a protruding manner on the casing surface, or on a member mounted inside the casing or the like, and also since the head portion of a screw does not protrude from a screw-fastening portion, the vapor chamber can be attached inside the casing without increasing the dimension in the thickness direction of the casing.

### BRIEF DESCRIPTION OF DRAWINGS

FIG. 1 is an explanatory view of a vapor chamber according to a first embodiment of the present disclosure.

FIG. 2 is an explanatory diagram of a first usage example of the vapor chamber according to the first embodiment of the present disclosure.

FIG. 3 is an explanatory view of a second usage example of the vapor chamber according to the first embodiment of the present disclosure.

FIG. 4 is an explanatory view of a vapor chamber according to a second embodiment of the present disclosure.

### DETAILED DESCRIPTION

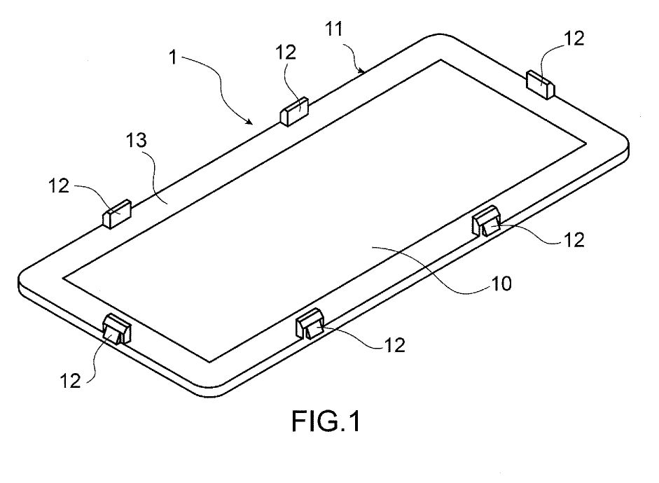

Hereinafter, a vapor chamber according to the first embodiment of the present disclosure will be described using the drawings. As shown in FIG. 1, a vapor chamber 1 according to the first embodiment includes a flat plate-like container 10, and a resin attachment member 11 mounted on the container 10. The container 10 is attached inside a casing (not shown) by the resin attachment member 11. By attaching the container 10 inside the casing, the vapor chamber 1 is thermally connected to a heat generator (not shown) mounted inside the casing.

The container 10 is formed by overlaying one plate-like body on other plate-like body facing the one plate-like body. A center portion of the one plate-like body is plastically deformed in a protruding shape. The portion of the one plate-like body, which protrudes outward and is plastically deformed in a protruding shape, is the protruding portion of the container 10, and the inside of the protruding portion is a cavity portion. The internal space of the cavity portion is depressurized by a deaeration process, and a working fluid is sealed therein. Moreover, a wick structure having capillary forces is provided in the depressurized cavity portion.

Although the shape of the container 10 is not particularly limited, in the vapor chamber 1, the container 10 has a rectangular shape in plan view (the appearance viewed from a vertical direction with respect to the plane of the vapor chamber 1). The thickness of the container 10 is not particularly limited, but may be, for example, 0.3 to 0.6 mm, and the thickness of each of the one plate-like body and the other plate-like body is not particularly limited, but may be, for example, 0.05 to 0.3 mm.

Regarding the material of the container 10, it is possible to give examples such as copper, copper alloy, aluminum, aluminum alloy, nickel, nickel alloy, stainless steel, titanium, and magnesium alloy. Further, if necessary, a corrosion preventive coating, for example, a plated metal may be provided on the surface of the container 10. A working fluid to be sealed in the internal space of the cavity portion can be appropriately selected according to the compatibility with the material of the container 10, and one example is water, and other examples are CFC substitutes, fluorocarbons, cyclopentane, ethylene glycol, and mixtures thereof with water. As the wick structure, examples include a sintered body of metal powder such as copper powder, metal mesh made of metal wires, grooves, and nonwoven fabric.

As shown in FIG. 1, in the vapor chamber 1, the resin attachment member 11 is provided on the container 10. In the vapor chamber 1, the attachment member 11 is provided on the peripheral edge portion of the container 10. In short, the attachment member 11 is provided to surround the container 10 along the outer peripheral portion of the container 10. The attachment member 11 has a frame-like base part 13 in plan view formed along the outer peripheral portion of the container 10, and attachment means formed on the base part 13. In FIG. 1, one fitting part 12 is used as the attachment means. The base part 13 and the container 10 are mutually located on the same plane or a substantially same plane.

As described above, the one fitting part 12 that is the attachment means is located on the outer peripheral portion of the vapor chamber 1 (container 10). The position of the one fitting part 12 on the base part 13 and the number of pieces of the one fitting part 12 to be provided on the base part 13 can be appropriately selected according to the situation of use. In the vapor chamber 1, a plurality of pieces (in FIG. 1, six pieces) of the one fitting part 12 are provided at approximately equal intervals on the base part 13.

Moreover, the other fitting part is formed in advance at a predetermined portion of the casing to which the vapor chamber 1 is attached, or of a member to be mounted on the casing. By fitting the one fitting part 12 into the other fitting part, the vapor chamber 1 is attached inside the casing.

The forms of the one fitting part 12 and the other fitting part are not particularly limited, but, for example, as shown in FIG. 1, the one fitting part 12 can be a protruding part having a claw protruding with respect to the plane of the container 10. In this case, the other fitting part may be a receiving part that receives the protruding part, and the protruding part may be freely fitted into and detached from the receiving part. Alternatively, the other fitting part may be a protruding part having a claw, and the one fitting part 12 may be a receiving part that receives the protruding part.

As described above, since the resin attachment member 11 is a fitting member, screw fastening using screws is not required, thereby facilitating the work of attaching the vapor chamber 1 inside the casing. In addition, since the resin attachment member 11 is the fitting member, there is no need to provide a screw hole portion for engaging with a screw in a protruding manner on the casing surface, or on a member to be mounted inside the casing, and also since the head portion of the screw does not protrude from the screw-fastening portion, the vapor chamber 1 can be attached inside the casing without increasing the dimension in the thickness direction of the casing.

A method of forming the resin attachment member 11 in the container 10 is not particularly limited, and, for example, the container 10 and the resin attachment member 11 can be formed as an integral unit by insert-molding in which after inserting an insert article (the container 10 provided with the wick structure and the working fluid) into a die in advance, the die is closed, and a resin is poured. Since the resin attachment member 11 is formed integrally with the container 10, the work of attaching the vapor chamber 1 inside the casing is facilitated.

The kind of resin of the resin attachment member 11 is not particularly limited, and examples include thermoplastic resins such as polyethylene, polypropylene, polyvinyl chloride, polystyrene, polyester, and polyamide. It is also possible to use a material obtained by further blending a material having excellent thermal conductivity, such as carbon particles and carbon fibers, with the resin.

Since the vapor chamber 1 can be thermally connected to a heat generator (not shown) in the casing by attaching the vapor chamber 1 inside the casing, the heat received from the heat generator can be smoothly spread over the entire plane of the container 10 by the heat transfer characteristics of the vapor chamber 1, thereby exhibiting excellent cooling performance and thermal diffusion performance. Moreover, since the base part 13 of the resin attachment member 11 and the container 10 are located on the same plane or a substantially same plane, the vapor chamber 1 can also be thermally connected in a smooth manner to the heat generator mounted in a thin casing, thereby exhibiting excellent cooling performance and thermal diffusion performance.

In the vapor chamber 1, since the container 10 and the attachment member 11 are formed as separate members, the attachment member 11 can be formed on the container 10 after a flattening step of the container 10. Therefore, even for the vapor chamber 1 having the attachment member 11, it is possible to obtain accurate flatness of the container 10. Further, since the attachment member 11 is provided on the container 10 after the flattening step of the container 10, it is possible to prevent the attachment member 11 from obstructing the flattening step of the container 10, thereby improving the efficiency of the flattening step of the container 10 and consequently the production efficiency of the vapor chamber 1.

Furthermore, in the vapor chamber 1, since the resin attachment member 11 is provided on the flat plate-like container 10, even if the container 10 is in the form of a thin flat plate, it is possible to improve the strength of the attachment member 11 by increasing the thickness of the resin constituting the attachment member 11, for example, the thickness of the one fitting part 12. Moreover, by using the attachment member 11 made of resin, even when an external stress is applied to the attachment member 11, it is possible to more reliably prevent deformation compared with a metal attachment member.

Moreover, even if the size and shape of the attachment region of the vapor chamber 1 in plan view vary, by changing the size and shape in plan view of the resin attachment member 11, the vapor chamber 1 can be attached inside the casing without changing the size and shape of the container 10. In short, without changing the dies for the one plate-like body and the other plate-like body constituting the container 10 and the wick structure, the vapor chamber 1 can be attached inside the casing by only changing the die for the attachment member 11. Consequently, the degree of freedom in designing the vapor chamber 1 and the heat generator is improved.

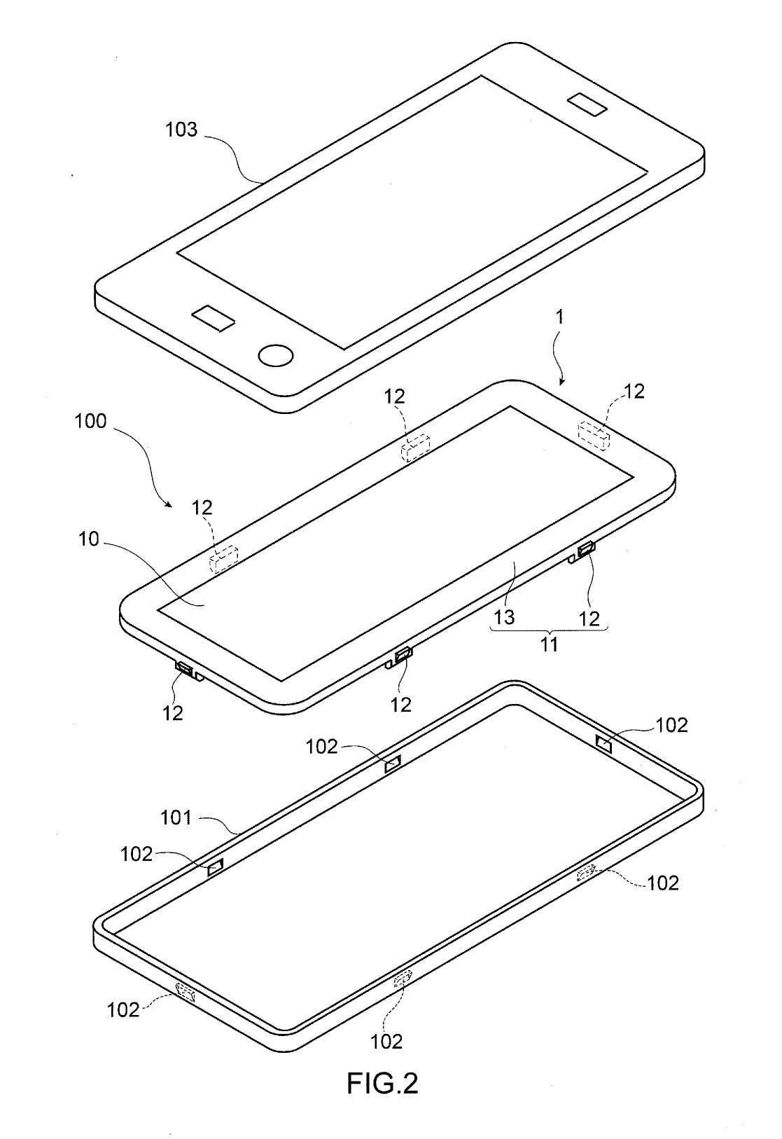

Next, the first usage example of the vapor chamber 1 according to the first embodiment will be described using the drawings. As shown in FIG. 2, the vapor chamber 1 can be mounted in a smartphone 100.

In FIG. 2, other fitting part 102 is formed in an inner-side peripheral edge portion of a back cover 101 constituting a casing of the smartphone 100. The shape and size of the vapor chamber 1 in plan view approximate to or are substantially the same as those of the back cover 101 in plan view. In addition, installed on the inner surface of the back cover 101 is a circuit board (not shown) on which electronic components, such as a central processing unit (CPU) that is a heat generator, are mounted. The one fitting part 12 of the attachment member 11 of the vapor chamber 1 is fitted into the other fitting part 102 formed in the inner-side peripheral edge portion of the back cover 101 on which the circuit board is installed, and further a display panel 103 is attached to the back cover 101 from the vapor chamber 1 side. Thus, the vapor chamber 1 can be attached inside the casing of the smartphone 100, and the container 10 of the vapor chamber 1 can be thermally connected to the electronic component such as the CPU that is the heat generator mounted on the circuit board.

Since the vapor chamber 1 can be attached inside the casing by fitting the one fitting part 12 of the vapor chamber 1 into the other fitting part 102 of the back cover 101, it is possible to more reliably prevent occurrence of distortion of the vapor chamber 1 and the back cover 101.

Furthermore, if necessary, by adopting a form in which a side face portion of the vapor chamber 1 (a side face portion of the attachment member 11) is exposed, or a form in which the side face portion of the attachment member 11 covers the side face portion of the back cover 101, it is possible to provide a form in which the side face portion of the vapor chamber 1 (the side face portion of the attachment member 11) constitutes a part of the casing of the smartphone 100, that is, a side face portion of the casing. As described above, since the occurrence of distortion of the vapor chamber 1 and the back cover 101 can be more reliably prevented, it is possible to improve the waterproof feature of the smartphone 100 by adopting the above-described form.

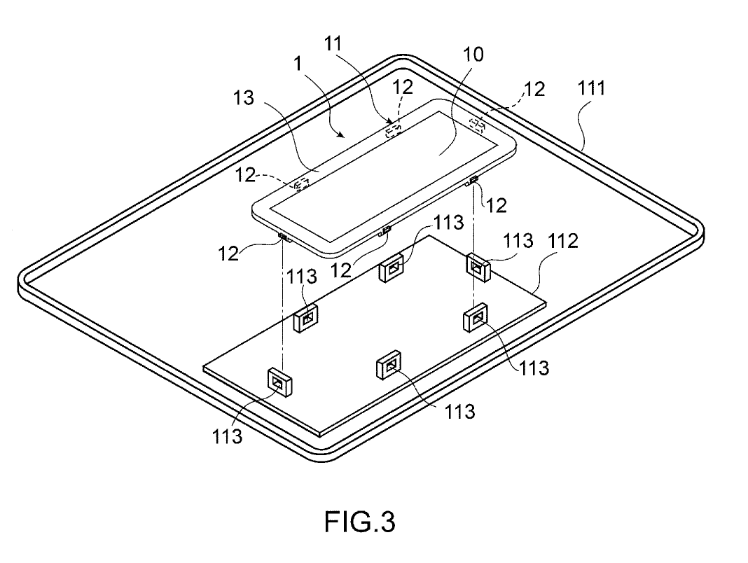

Next, the second usage example of the vapor chamber 1 according to the first embodiment will be described using the drawings. As shown in FIG. 3, the vapor chamber 1 can be mounted in a tablet terminal.

In FIG. 3, a circuit board 112 on which electronic components (not shown) such as a CPU that is a heat generator are mounted is installed in a bottom-side casing 111 of the tablet terminal. On the circuit board 112, other fitting part 113 is formed in the periphery of the electronic components such as the CPU as the heat generator. The shape and size in plan view of the vapor chamber 1 are smaller than the shape and size in plan view of the bottom-side casing 111 that is the tablet terminal. Further, the one fitting part 12 of the attachment member 11 of the vapor chamber 1 is located to correspond to the position of the other fitting part 113 provided on the circuit board 112.

Thus, by fitting the one fitting part 12 of the attachment member 11 of the vapor chamber 1 into the other fitting part 113 formed on the circuit board 112, the vapor chamber 1 can be attached inside the bottom-side casing 111 of the tablet terminal. Moreover, by fitting the one fitting part 12 of the attachment member 11 into the other fitting part 113 of the circuit board 112, the container 10 of the vapor chamber 1 can be thermally connected to the heat generator mounted on the circuit board 112.

Conventionally, when thermally connecting a radiator plate which is a plate material to a heat generator such as an electronic component mounted on a circuit board, the radiator plate is placed on the heat generator, and the peripheral edge portion of the radiator plate needs to be fastened to the circuit board with a screw. In short, a screw hole portion for engaging with a screw is provided in a protruding manner on the circuit board and also the head portion of the screw protrudes from the screw-fastening portion, and therefore the dimension in the thickness direction of the casing of the tablet terminal cannot be sufficiently decreased. On the other hand, in the second usage example, since the resin attachment member 11 is a fitting member, it is unnecessary to provide the screw hole portion for engaging with the screw in a protruding manner on the circuit board 112 and also the head portion of the screw does not protrude from the screw-fastening portion, and therefore it is possible to attach the vapor chamber 1 inside the bottom-side casing 111 without increasing the dimension in the thickness direction of the casing of the tablet terminal.

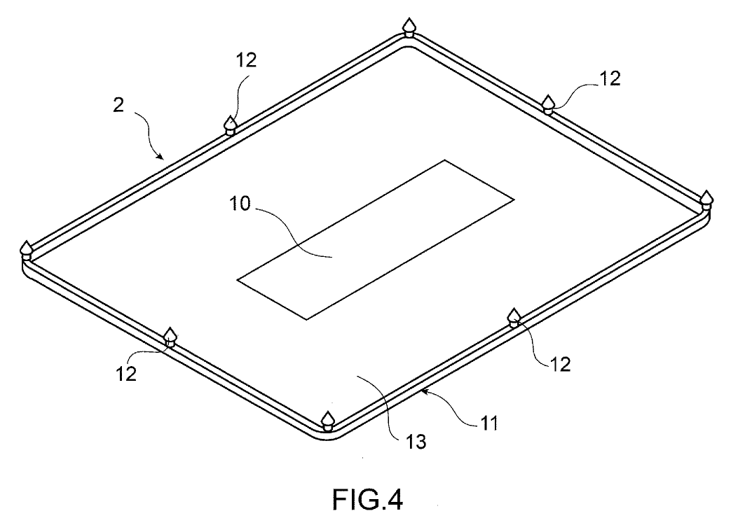

Next, a vapor chamber according to the second embodiment of the present disclosure will be described using the drawings. In the vapor chamber 1 according to the first embodiment, the attachment member 11 has the base part 13 in the form of a frame in plan view, whereas a vapor chamber 2 according to the second embodiment is in a form in which, as shown in FIG. 4, the base part 13 of the attachment member 11 is like a flat plate in plan view, and the container 10 is installed at a desired position on the flat plate-like base part 13. The desired position may be, for example, a position corresponding to an electronic component such as a CPU mounted on the circuit board (not shown). Further, in the vapor chamber 1, the protruding part having the claw protruding with respect to the plane of the container 10 is formed as the one fitting part 12 which is the attachment means formed on the base part 13, whereas in the vapor chamber 2, as shown in FIG. 4, a protruding part having a conical head portion protruding with respect to the plane of the container 10 is formed instead as the one fitting part 12. In the vapor chamber 2, a plurality of pieces (in FIG. 4, eight pieces) of the one fitting part 12 are provided on the peripheral edge portion of the base part 13.

The vapor chamber 2 according to the second embodiment can be manufactured by modifying, for example, the die for insert-molding for use in the manufacture of the vapor chamber 1 according to the first embodiment to conform to the specifications of the flat plate-like base part 13 and the protruding part having the conical head portion.

The vapor chamber 2 is a part of the casing, and, in FIG. 4, it is one of the casing portions having a rectangular shape in plan view. Further, on the peripheral edge portion of the other casing portion (not shown) having a rectangular shape in plan view, other fitting part, which is a receiving part (recessed receiving part) that is fitted with the one fitting part 12 and receives the protruding part, is formed. On the inner surface of the other casing portion, for example, a circuit board on which electronic components such as a CPU are mounted is installed. By fitting the one fitting part 12 into the other fitting part, the one casing portion that is the vapor chamber 2 and the other casing portion are coupled together, thereby forming the casing in which the container 10 is placed. In short, by fitting the one fitting part 12 of the vapor chamber 2 into the other fitting part of the other casing portion, the casing in which the container 10 is placed at a desired position (for example, a position facing the electronic component such as the CPU mounted on the circuit board) is formed.

Since the vapor chamber 2 is in a form in which the container 10 is installed in one of the casing portions, it is possible to prevent a local temperature rise at the position of the casing corresponding to the region of the electronic component such as the CPU. An example of the casing is a casing of a notebook type personal computer.

Next, other embodiment of the vapor chamber of the present disclosure will be described. In the vapor chamber of each of the above-described embodiments, the entire peripheral edge portion of the container is surrounded by the base part of the attachment member, but instead the base part of the attachment member may be provided on a part of the peripheral edge portion of the container. Further, in the vapor chamber of each of the above-described embodiments, the container and the attachment member are integrated with each other, but instead the container and the attachment member may be provided as separate bodies. Regarding the case where the container and the attachment member are provided as separate bodies, an example is a form in which the container is fitted into a molded attachment member.

In the vapor chamber of each of the above-described embodiments, the one fitting part is used as means for attaching the attachment member, but instead another attachment means such as a locking member may be used. Alternatively, as the means for attaching the attachment member, a through-hole having a screw groove is formed in the base part instead of the one fitting part, or together with the one fitting part, and a screw is inserted into the through-hole to attach the vapor chamber inside the casing. In this case, by forming a hole portion having a screw groove in the casing at a position corresponding to the position of the through-hole having the screw groove of the vapor chamber, the vapor chamber is fastened in the casing with the screw. Further, as the one fitting part 12, the protruding part having the claw and the protruding part having the conical head portion are used in the vapor chamber according to the first embodiment and in the vapor chamber according to the second embodiment, respectively, but instead it is also possible to adopt a form in which both of the protruding part having the claw and the protruding part having the conical head portion are used.

Since a vapor chamber of the present disclosure excels in the cooling performance for a heat generator mounted in a thin casing and the thermal diffusion performance from the heat generator, the vapor chamber has a high utility value, particularly, for example, in the field of electric and electronic equipment which is required to be thinner, such as smartphones, tablet terminals, and notebook type personal computers.

1. A vapor chamber to be attached inside a casing, the vapor chamber comprising:
a flat plate-like container having a cavity portion;
a wick structure provided to the cavity portion;
a working fluid sealed in the cavity portion; and
a resin attachment member, provided on the container, for attachment into the casing.

2. The vapor chamber according to claim 1, wherein the resin attachment member is integrally molded with the container.

3. The vapor chamber according to claim 1, wherein the resin attachment member is provided in a peripheral edge portion of the container.

4. The vapor chamber according to claim 1, wherein the resin attachment member is a fitting member which is detachably attached to a fitting part in the casing.

5. The vapor chamber according to claim 1, wherein the vapor chamber is for cooling a heat generator mounted in a smartphone, a tablet terminal, or a notebook type personal computer.

6. The vapor chamber according to claim 2, wherein the resin attachment member is provided in a peripheral edge portion of the container.

7. The vapor chamber according to claim 2, wherein the resin attachment member is a fitting member which is detachably attached to a fitting part in the casing.

8. The vapor chamber according to claim 2, wherein the vapor chamber is for cooling a heat generator mounted in a smartphone, a tablet terminal, or a notebook type personal computer.
